(19) United States
(12) Patent Application Publication
(10) Pub. No.: US 2014/0313678 A1
(43) Pub. Date: Oct. 23, 2014

(54) MOUNTING DEVICE FOR EXPANSION CARD

(71) Applicants: Hon Hai Precision Industry Co., Ltd., New Taipei (TW); Hong Fu Jin Precision Industry (ShenZhen) Co., Ltd., Shenzhen (CN)

(72) Inventors: XIAO-GANG YIN, Shenzhen (CN); JUN-HUI WANG, Shenzhen (CN)

(73) Assignees: Hon Hai Precision Industry Co., Ltd., New Taipei (TW); Hong Fu Jin Precision Industry (ShenZhen) Co., Ltd., Shenzhen (CN)

(21) Appl. No.: 14/029,749

(22) Filed: Sep. 17, 2013

(30) Foreign Application Priority Data
Apr. 19, 2013 (CN) 2013101372257

(51) Int. Cl. H05K 7/12

(52) U.S. Cl. CPC H05K 7/12
USPC 361/748; 248/205.1

(57) ABSTRACT

A mounting device for mounting one end of an expansion card plugged in a circuit board includes a bracket to be mounted on the circuit board, and a mounting member slidably mounted to the bracket. The bracket includes a top plate forming a number of parallel dentate members. The mounting member includes a supporting portion for clamping the end of the expansion card, and a positioning portion adjustable to lock to one of the dentate members for positioning the mounting member relative to the bracket.

### BACKGROUND

1. Technical Field

The present disclosure relates to a device for mounting an expansion card.

2. Description of Related Art

In installing an expansion card, one end of the expansion card is generally fixed to a chassis, while an opposite end of the expansion card is cantilevered. As a result, when an expansion card is long and horizontally fixed to the chassis, the cantilevered end may droop and cause damage to the expansion card.

### BRIEF DESCRIPTION OF THE DRAWINGS

Many aspects of the present embodiments can be better understood with reference to the drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a mounting device with an expansion card; wherein the mounting device includes a bracket and a mounting member.

FIG. 2 is an enlarged view of the bracket and the mounting member of FIG. 1, but viewed from another perspective.

FIG. 3 is an inverted view of the bracket and the mounting member of FIG. 2.

FIG. 4 is an assembled, isometric view of the mounting device of FIG. 1, together with the expansion card.

FIG. 5 is a cross-sectional view taken along the line V-V of FIG. 4.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

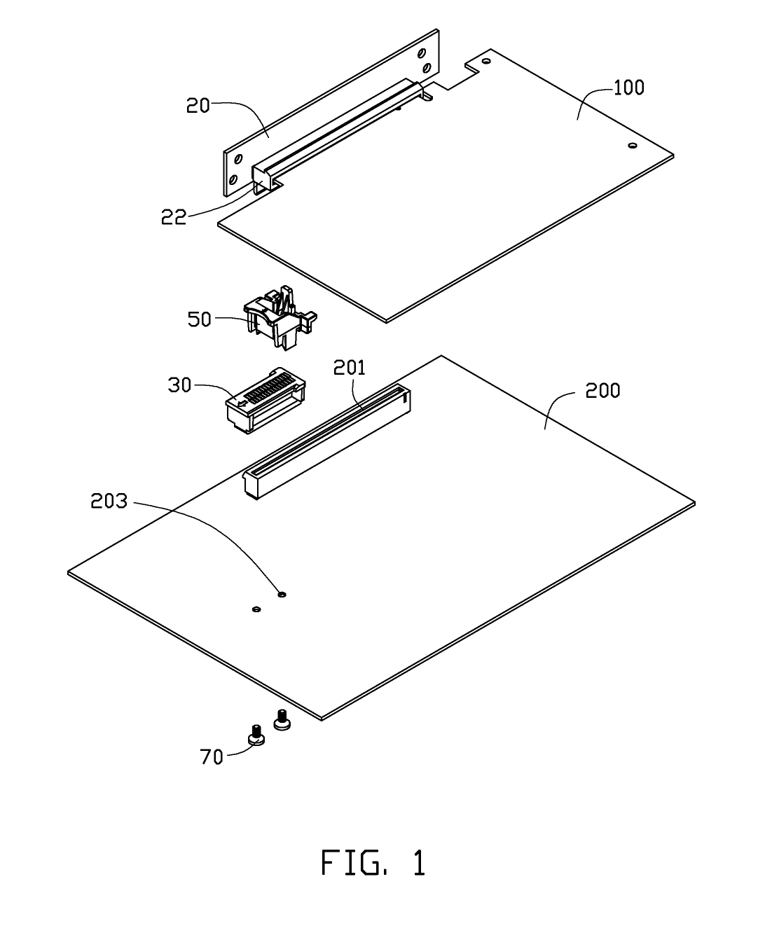

Referring to FIG. 1, an exemplary embodiment of a mounting device for an expansion card 100 includes a circuit board 200 mounted in a chassis (not shown), a bracket 30, and a mounting member 50. The circuit board 200 includes a socket 201. A conversion card 20 is plugged in the socket 201, the conversion card perpendicular to the circuit board 200. A connector 22 is set on the conversion card 20, and the connector 22 is parallel to the circuit board 200. Two through holes 203 are defined in the circuit board 200, adjacent to one end of the socket 201.

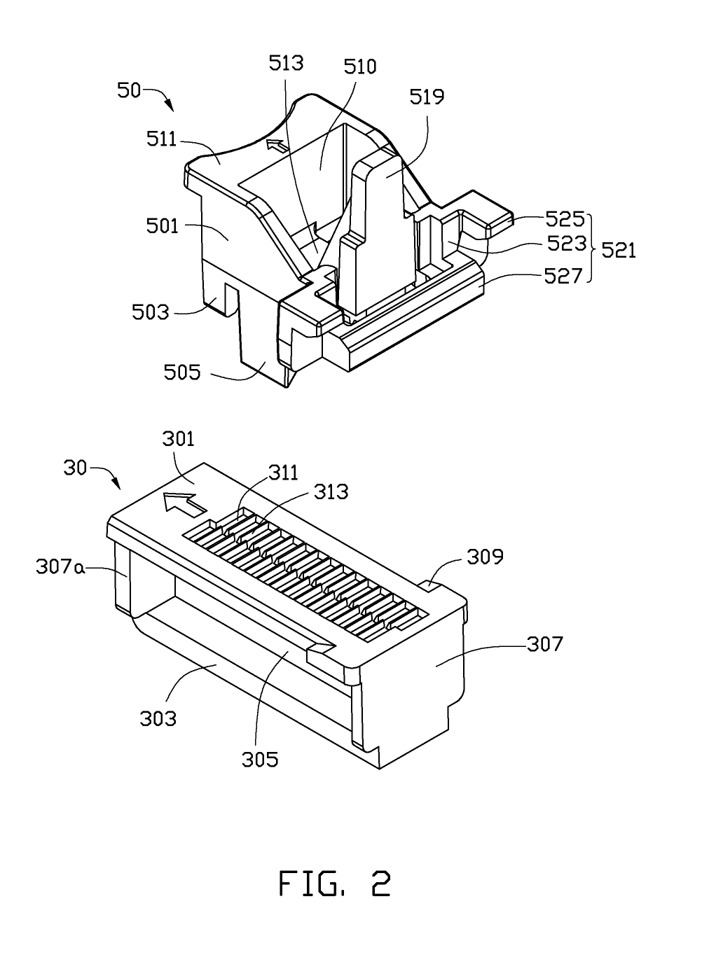

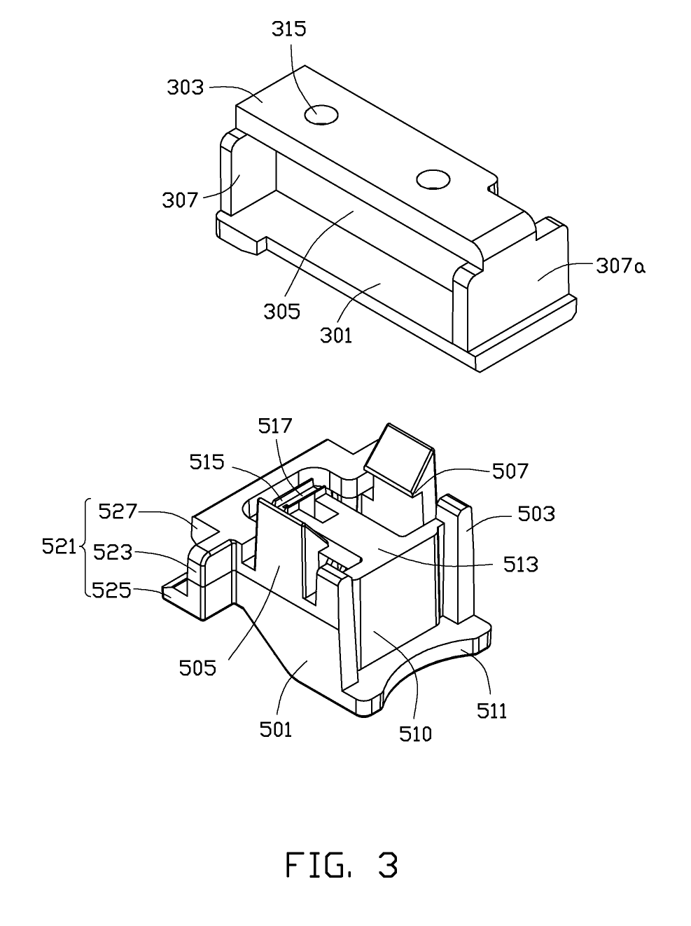

Referring to FIG. 2 and FIG. 3, the bracket 30 includes a top plate 301, a bottom plate 303 parallel to the top plate 301, a supporting plate 305 connected between corresponding sides of the top plate 301 and the bottom plate 303, and a first limiting plate 307 and a second limiting plate 307a formed at opposite ends of the supporting plate 305 and connected between opposite ends of the top plate 301 and the bottom plate 303. Two blocks 309 are formed at opposite sides of one end of the top plate 301 adjacent to the first limiting plate 307. Two receiving slots 311 communicating with each other are defined in a top surface of the top plate 301. A plurality of parallel dentate members 313 is formed in each receiving slot 311. The dentate members 313 in one of the receiving slots 311 are staggered from the dentate members 313 in the other receiving slot 311. Two screw holes 315 are defined in the bottom plate 303.

The mounting member 50 includes two parallel sidewalls 501, an end wall 510 connected between first ends of the sidewalls 501, and a supporting portion 521 formed at second ends of the sidewalls 501. Two installing arms 503 extend down from bottoms of the sidewalls 501, and at opposite sides of the end wall 510. Two sliding arms 505 extend down from the bottom of the sidewalls 501 and are located between the supporting portion 521 and the end wall 510. Two hooks 507 extend toward each other from bottom ends of the sliding arms 505. An operation portion 511 extends out from a top of the end wall 510. A resilient positioning portion 513 extends toward the supporting portion 521 from a bottom of the end wall 510. Two parallel raised portions 515 are formed on a bottom surface of a distal end of the positioning portion 513. A positioning slot 517 is formed between the raised portions 515. A handle 519 extends from a top surface of the distal end of the positioning portion 513 opposite to the first surface. The supporting portion 521 includes two blocking portions 523 extending out from the sidewalls 501, two first clamping portions 525 perpendicularly extending from tops of the blocking portions 523 away from the end wall 510, and a second clamping portion 527 formed between bottoms of the blocking portions 523.

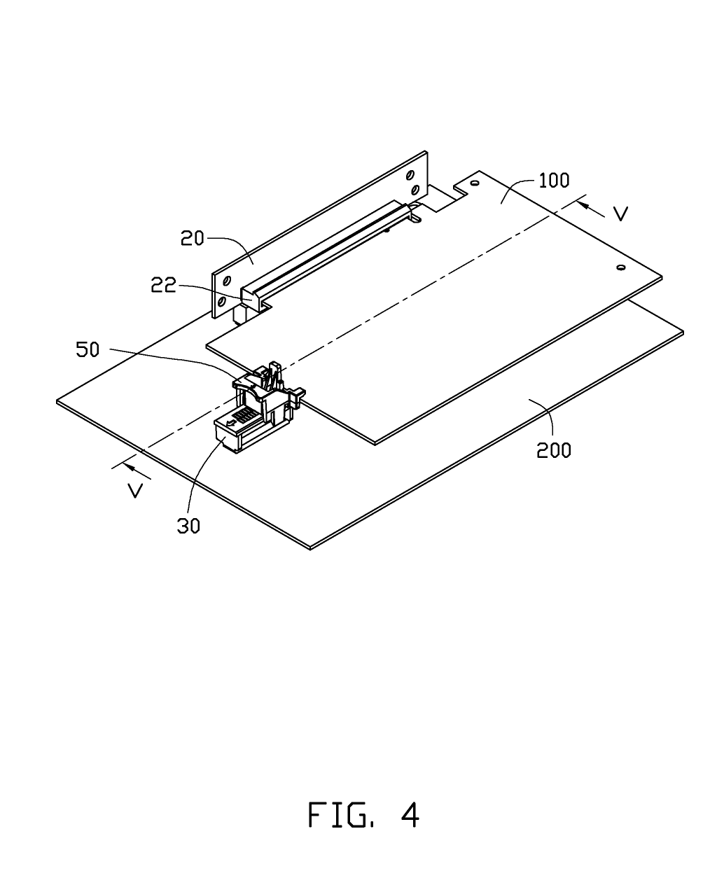

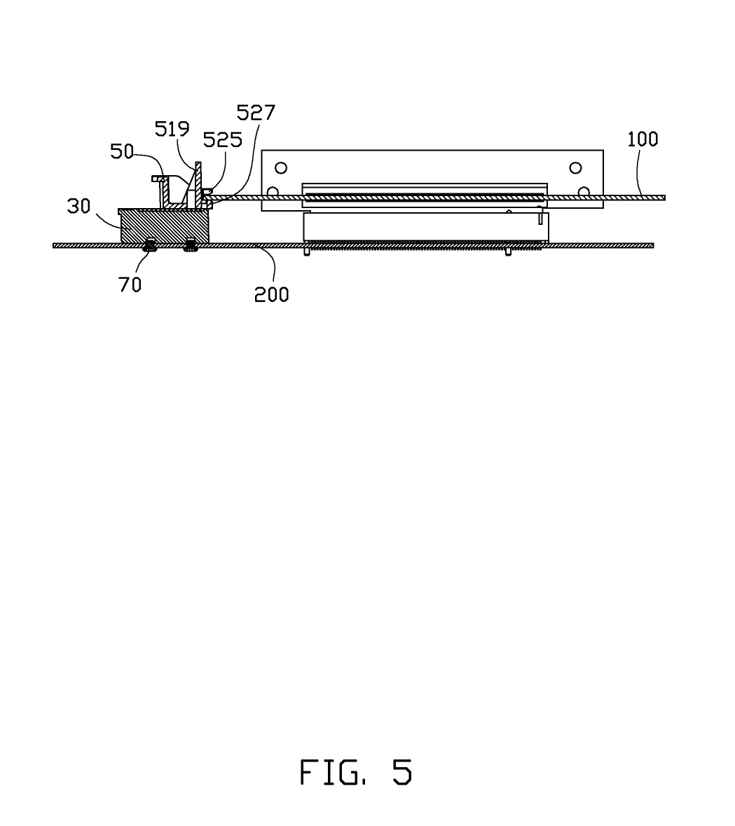

Referring to FIG. 4 and FIG. 5, in assembly, the bracket 30 is fixed to the circuit board 200 through two screws 70 extending through the through holes 203 to screw in the screw holes 315. The mounting member 50 bestrides on the bracket 30. The second clamping portion 527 faces to the first limiting plate 307. The installing arms 503 and the sliding arms 505 slidably sandwich the top plate 301. The hooks 507 are locked to a bottom of the top plate 301. Thus, the mounting member 50 is slidably mounted to a top of the bracket 30 and limited between the first limiting plate 307 and the second limiting plate 307a. The blocks 309 are used for preventing the mounting member 50 from disengaging from the bracket 30. The positioning slot 517 can mate with one of the dentate members 313 to position the mounting member 50 relative to the bracket 30. The dentate members 313 of the receiving slots 311 are staggered to increase density of the dentate members 313, which can increase positional accuracy between the mounting member 50 and the bracket 30.

When mounting the expansion card 100, the expansion card 100 is plugged in the connector 22. The handle 519 is operated to deform up the positioning portion 513, until the positioning slot 517 releases one of the dentate members 313. The mounting member 50 is then slid to the expansion card 100, until the blocking portions 523 abut against an end of the expansion card 100. The first clamping portions 525 and the second clamping portion 527 sandwich the end of the expansion card 100. The handle 519 is released to restore the positioning portion 513. The positioning slot 517 mates with one of the dentate members 313 to position the mounting member 50 relative to the bracket 30. Therefore, the mounting member 50 is adjustable to suit for different sizes of expansion cards.

When releasing the expansion card 100, the handle 519 is operated to deform up the positioning portion 513, until the positioning slot 517 releases one of the dentate members 313. The mounting member 50 is then slid away from the expansion card 100.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A mounting device for positioning an end of an expansion card, the mounting device comprising:
a bracket to be mounted on a circuit board and located at the end of the expansion card, wherein the bracket comprises a top plate forming a plurality of parallel dentate members; and
a mounting member slidably mounted to the bracket, wherein the mounting member comprises a supporting portion for clamping the end of the expansion card, and a positioning portion adjustable to lock to one of the dentate members for positioning the mounting member relative to the bracket.

2. The mounting device of claim 1, wherein two receiving slots communicating with each other are defined in a top surface of the top plate, the plurality of parallel dentate members are formed in the receiving slots, the dentate members in one of the receiving slots are staggered from the dentate members in the other receiving slot.

3. The mounting device of claim 1, wherein the bracket further comprises a bottom plate parallel to the top plate, a supporting plate connected between the top plate and the bottom plate, and a first limiting plate and a second limiting plate formed at opposite ends of the supporting plate, the mounting member is slidable between the first limiting plate and the second limiting plate.

4. The mounting device of claim 3, wherein two blocks are formed at opposite sides of one end of the top plate adjacent to the first limiting plate, for preventing the mounting member from disengaging from the bracket.

5. The mounting device of claim 3, wherein the mounting member comprises two parallel sidewalls and an end wall connected between first ends of the sidewalls, the supporting portion is formed at second ends of the sidewalls.

6. The mounting device of claim 5, wherein two sliding arms extend down from bottoms of the sidewalls, two hooks extend toward each other from the sliding arms, the sliding arms slidably sandwich the top plate of the bracket, the hooks are locked to a bottom of the top plate.

7. The mounting device of claim 6, wherein the positioning portion extends toward the supporting portion from an inner surface of the end wall, two parallel raised portions are formed at a bottom surface of a distal end of the positioning portion, a positioning slot is formed between the raised portions, for mating with one of the dentate members.

8. The mounting device of claim 7, wherein a handle extends from a top surface of the distal end of the positioning portion, facilitating the positioning portion to be deformed to release the positioning slot from one of the dentate members.

9. The mounting device of claim 7, wherein the supporting portion comprises two blocking portions extending out from the sidewalls, two first clamping portions perpendicularly extending from tops of the blocking portions, and a second clamping portion formed between bottoms of the blocking portions, the blocking portions abut against the end of the expansion card, the first clamping portions and the second clamping portion sandwich the end of the expansion card.

10. An assembly comprising:
a circuit board comprising a socket;
a conversion card plugged in the socket and perpendicular to the circuit board, the conversion card comprising a connector parallel to the circuit board;
an expansion card plugged in the connector of the conversion card and parallel to the circuit board;
a bracket mounted on the circuit board and located at the end of the expansion card, wherein the bracket comprises a top plate forming a plurality of parallel dentate members; and
a mounting member slidably mounted to the bracket, wherein the mounting member comprises a supporting portion for clamping the end of the expansion card, and a positioning portion adjustable to lock to one of the dentate members for positioning the mounting member relative to the bracket.

11. The assembly of claim 10, wherein two receiving slots communicating with each other are defined in a top surface of the top plate, the plurality of parallel dentate members are formed in the receiving slots, the dentate members in one of the receiving slots are staggered from the dentate members in the other receiving slot.

12. The assembly of claim 10, wherein the bracket further comprises a bottom plate parallel to the top plate, a supporting plate connected between the top plate and the bottom plate, and a first limiting plate and a second limiting plate formed at opposite ends of the supporting plate, the mounting member is slidable between the first limiting plate and the second limiting plate.

13. The assembly of claim 12, wherein two blocks are formed at opposite side of one end of the top plate adjacent to the first limiting plate, for preventing the mounting member from disengaging from the bracket.

14. The assembly of claim 12, wherein the mounting member comprises two parallel sidewalls and an end wall connected between first ends of the sidewalls, the supporting portion is formed at second ends of the sidewalls.

15. The assembly of claim 14, wherein two sliding arms extend down from a bottom of the sidewalls, two hooks extend toward each other from the sliding arms respectively, the sliding arms slidably sandwich the top plate of the bracket, the hooks are locked to a bottom of the top plate.

16. The assembly of claim 15, wherein the positioning portion extends toward the supporting portion from an inner surface of the end wall, two parallel raised portions are formed at a bottom surface of a distal end of the positioning portion, a positioning slot is formed between the raised portions, for mating with one of the dentate members.

17. The assembly of claim 16, wherein a handle extends from a top surface of the distal end of the positioning portion, facilitating the positioning portion to be deformed to release the positioning slot from one of the dentate members.

18. The assembly of claim 16, wherein the supporting portion comprises two blocking portions extending out from the sidewalls, two first clamping portions perpendicularly extending from tops of the blocking portions, and a second clamping portion formed between bottoms of the blocking portions, the blocking portions abut against the end of the expansion card, the first clamping portions and the second clamping portion sandwich the end of the expansion card.
